(19) United States
(12) Patent Application Publication
(10) Pub. No.: US 2024/0203733 A1
(43) Pub. Date: Jun. 20, 2024

(54) MATERIAL LAYER DEPOSITION METHODS, MATERIAL LAYER STACKS, SEMICONDUCTOR PROCESSING SYSTEMS, AND RELATED COMPUTER PROGRAM PRODUCTS

(71) Applicant: ASM IP Holding B.V., Almere (NL)

(72) Inventors: Omar Elleuch, Litchfield Park, AZ (US); Yanfu Lu, Phoenix, AZ (US); Caleb Miskin, Mesa, AZ (US); Alexandros Demos, Scottsdale, AZ (US)

(21) Appl. No.: 18/535,715

(22) Filed: Dec. 11, 2023

Related U.S. Application Data
(60) Provisional application No. 63/387,683, filed on Dec. 15, 2022.

(51) Int. Cl. H01L 21/02; C23C 16/52

(52) U.S. Cl. CPC H01L 21/0262; C23C 16/52; H01L 21/02532

(57) ABSTRACT

A material layer deposition method includes supporting one and only one substrate in a chamber arrangement, exposing the substrate to a first material layer precursor and a second material layer precursor, and forming a first material layer overlaying the substrate using the first material layer precursor and the second material layer precursor. The first material layer is exposed to the first material layer to the first material layer precursor and a second material layer formed onto the first material layer using the first material layer precursor. The second material layer precursor includes a germanium-containing material layer precursor and the first material layer precursor includes at least one of trisilane (Si₃H₈) and tetrasilane (Si₄H₁₀). Material layer stacks, semiconductor processing systems, and computer program products are also described.

### CROSS-REFERENCE TO RELATED APPLICATION(S)

This Application claims the benefit of U.S. Provisional Application 63/387,683 filed on Dec. 15, 2022, the entire contents of which are incorporated herein by reference.

### FIELD OF INVENTION

The present disclosure generally relates to fabricating semiconductor devices. More particularly, the present disclosure relates to the deposition of material layer stacks onto substrates used during the fabrication of semiconductor devices.

### BACKGROUND OF THE DISCLOSURE

Semiconductor devices, such as circuit elements in integrated circuits employed in power electronics and memory devices, are commonly fabricated by depositing films onto substrates and forming devices features using the deposited film. Film deposition is generally accomplished by supporting a substrate in a reaction chamber, heating the substrate to a desired film deposition temperature, and flowing a film precursor to the substrate. As the film precursor flows across the substrate a material typically develops on the substrate, generally at a rate corresponding to temperature of the substrate and environmental conditions within the reaction chamber. Once the film reaches desired thickness the substrate is typically removed from the reaction chamber and sent on for further processing, as appropriate for the semiconductor processing system being fabricated.

In some semiconductor manufacturing processes it may be advantageous to form a film stack on the substrate including films of different composition to fabricate a semiconductor device. For example, semiconductor devices having three-dimensional (3D) architectures such as finned field-effect transformers and gate-all-around devices as well as 3D DRAM devices may be scaled by forming the devices from monolithic film stacks. Monolithic film stacks, while advantageous that devices may be formed with greater height in relation to two-dimensional devices. In this aspect, within the field of memory devices and particularly relating to DRAMs, as scaling is slowing down, monolithic stacking has started to receive interest to realize the manufacturing of 3D DRAM devices. However, even with the advantages associated with three-dimensional device architectures, challenges remain. For example, depositing multiple films require flowing different types of precursors for the different types of films included in the film stack, limiting throughput of the reaction chamber employed for the deposition operation. Each layer in the film also serves as a location where a defect may develop, any given defect in a lower level potentially generating defects (i.e. decorating) films overlying the defect, reducing yield of the manufacturing process employed to fabricate a desired semiconductor device.

Various approaches exist to address the challenges of forming film stacks. For example batch and mini-batch reactors may be employed to form film stacks on groups of substrates. Deposition conditions including pressure and temperature within the reaction chamber during film deposition may be carefully controlled, limiting defect generation. And inline metrology may be employed to measure film thickness across the substrate to alert personnel controlling the reaction chamber of the need for adjustment, maintenance, and/or to schedule service of the reaction chamber employed for the deposition operation. For example, cross-substrate thickness variation may be measured subsequent to deposition of the film stack.

Such methods and systems have generally been considered suitable for their intended purpose. However, there remains a need in the art for improved film deposition methods, film stacks, semiconductor processing systems, and related computer program products. The present disclosure provides a solution to this need.

### SUMMARY OF THE DISCLOSURE

A material layer deposition method is provided. The material layer deposition method includes supporting one and only one substrate in a chamber arrangement, exposing the substrate to a first material layer precursor and a second material layer precursor, and forming a first material layer overlaying the substrate using the first material layer precursor and the second material layer precursor. The first material layer is exposed to the first material layer to the first material layer precursor and a second material layer formed onto the first material layer using the first material layer precursor. The second material layer precursor includes a germanium-containing material layer precursor and the first material layer precursor includes at least one of trisilane (Si₃H₈) and tetrasilane (Si₄H₁₀).

In addition to one or more of the features described above, or as an alternative, further examples of the method may include may that the first material layer precursor consists essentially of trisilane (Si₃H₈).

In addition to one or more of the features described above, or as an alternative, further examples of the method may include that the first material layer precursor consists essentially of tetrasilane (Si₄H₁₀).

In addition to one or more of the features described above, or as an alternative, further examples of the method may include co-flowing the first material layer precursor with a carrier/diluent fluid including nitrogen (N₂) gas.

In addition to one or more of the features described above, or as an alternative, further examples of the method may include maintaining a first material layer deposition pressure within the chamber arrangement that is between about 1 Torr and about 50 Torr during forming the first material layer onto the substrate. A second material layer deposition pressure within the chamber arrangement that is between about 1 Torr and about 50 Torr during forming the second material layer onto the first material layer.

In addition to one or more of the features described above, or as an alternative, further examples of the method may include maintaining the substrate at a first material layer deposition temperature that is between about 500 degrees Celsius and about 800 degrees Celsius during forming the first material layer overlaying the substrate. The substrate may be maintained at a second material layer deposition temperature that is between about 500 degrees Celsius and about 800 degrees Celsius during forming the second material layer onto the first material layer.

In addition to one or more of the features described above, or as an alternative, further examples of the method may include that forming the first material layer onto the substrate includes forming the first material layer at a first material layer deposition rate that is between about 12 angstroms per second and about 60 angstroms per second.

In addition to one or more of the features described above, or as an alternative, further examples of the method may include that forming the second material layer onto the substrate comprises forming the second material layer at second material layer deposition rate that is between about 5 angstroms per second and about 40 angstroms per second.

In addition to one or more of the features described above, or as an alternative, further examples of the method may include acquiring a first temperature measurement and a second temperature measurement, determining a differential between the first temperature measurement and the second temperature measurement, and comparing the determined differential to a predetermined temperature differential. Heat communicated into the chamber arrangement may be throttled (e.g., increased or decreased) when the determined differential is greater than the predetermined temperature differential.

In addition to one or more of the features described above, or as an alternative, further examples of the method may include that throttling heat communicated into the chamber arrangement includes throttling one or more of a plurality of upper heater elements supported above the chamber arrangement relative to another of the upper heater elements, and throttling one or more of a plurality of lower heater elements supported below the chamber arrangement relative to another of the lower heater elements.

In addition to one or more of the features described above, or as an alternative, further examples of the method may include that the determined differential is an average substrate temperature differential, and the method may further include controlling average substrate temperature using the first temperature measurement and the second temperature measurement.

In addition to one or more of the features described above, or as an alternative, further examples of the method may include that the determined differential is a center-to-edge substrate temperature differential, the method may further include controlling a center-to-edge temperature differential of the substrate using the first temperature measurement and the second temperature measurement.

In addition to one or more of the features described above, or as an alternative, further examples of the method may include that the determined differential is a divider-to-substrate temperature differential, and the method may further include controlling a divider-to-substrate temperature differential using the first temperature measurement and the second temperature measurement.

In addition to one or more of the features described above, or as an alternative, further examples of the method may include that (a) the first temperature measurement and the second temperature measurement are acquired optically, (b) the first temperature measurement is acquired optically and the second temperature measurement is acquired tactilely, and (c) the first temperature measurement and the second temperature measurement are acquired tactilely.

In addition to one or more of the features described above, or as an alternative, further examples of the method may include forming a 3D DRAM semiconductor device using the first material layer and the second material layer.

A material layer stack is provided. The material layer stack includes between 20 material layer pairs and 400 material layer pairs overlaying a substrate. Each of the between 20 material layer pairs and 400 material layer pairs include a first material and a second material layer deposited using the above-described material layer deposition method.

In addition to one or more of the features described above, or as an alternative, further examples of the material layer stack may include that the first material layer and the second material layer have thicknesses that are between about 5 nanometers and about 50 nanometers; that the first material layers have a within-material layer thickness variation that is between about 1 nanometer and about 0.2 nanometers; and that the second material layers have a within-material layer thickness variation that is between about 2 nanometers and about 0.4 nanometers.

In addition to one or more of the features described above, or as an alternative, further examples of the material layer stack may include that the first material layers of the between 20 material layer pairs and 400 material layer pairs have layer-to-layer thickness variation that is less than about 2 nanometers, and that the second material layers of the between 20 material layer pairs and the 400 material layer pairs have layer-to-layer thickness variation that is less than about 10 nanometers.

A semiconductor processing system is provided. The semiconductor processing system includes a precursor arrangement, a chamber arrangement, and a controller. The precursor arrangement is configured to provide a first material layer precursor and a second material layer precursor, the second material layer precursor including a germanium-containing material layer precursor, and the first material layer precursor including at least one of trisilane (Si₃H₈) and tetrasilane (Si₄H₁₀). The chamber arrangement is connected to the precursor arrangement and house a substrate support, the substrate supported support for rotation about a rotation axis. The controller is operably connected to the chamber arrangement and the precursor delivery arrangement. The controller further includes a processor disposed in communication with a memory including a non-transitory machine-readable medium having a plurality of program modules containing instructions that, when read by the processor, cause the processor to support one and only one substrate within the chamber arrangement; expose the substrate to a first material layer precursor and a second material layer precursor; form a first material layer overlaying the substrate using the first material layer precursor and the second material layer precursor; expose the first material layer to the first material layer precursor; and form a second material layer onto the first material layer using the first material layer precursor.

A computer program product is provided. The computer program product includes a non-transitory machine-readable medium having a plurality of program modules recorded thereon containing instructions that, when read by a processor, cause the processor to execute operations that support one and only one substrate in a chamber arrangement of a semiconductor processing system; expose the substrate to a first material layer precursor and a second material layer precursor provided by a precursor delivery arrangement connected to the chamber arrangement; form a first material layer overlaying the substrate using the first material layer precursor and the second material layer precursor; expose the first material layer to the first material layer precursor; form a second material layer onto the first material layer using the first material layer precursor, the second material layer precursor including a germanium-containing material layer precursor, and the first material layer precursor including at least one of trisilane (Si₃H₈) and tetrasilane (Si₄H₁₀).

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain examples, which are intended to illustrate and not to limit the invention.

FIG. 1 is a schematic view of a semiconductor processing system in accordance with the present disclosure, showing a chamber arrangement supporting one and only substrate during deposition of a material layer stack onto an upper surface of the substrate;

FIG. 2 a sectional view of the chamber arrangement of FIG. 1 according to an example of the present disclosure, showing a substrate support arranged within a chamber body for flowing a material layer precursor across the substrate to deposit the material layer stack;

FIG. 3 is a sectional view of the material layer stack of FIG. 1 according to an example of the present disclosure, showing a first material layer pair overlaying the substrate and one or more second material layer pair overlaying the first material layer pair;

FIGS. 4-7 is a block diagram of a material layer deposition method that may be employed to form the material layer stack of FIG. 1, showing operations of the method according to an illustrative and non-limiting example of the method; and

FIGS. 8 and 9 are charts of deposition rate versus substrate temperature for material layer precursors including trisilane and tetrasilane, showing deposition rates when nitrogen is employed as a carrier/diluent fluid in comparison to other carrier/diluent fluids.

It will be appreciated that elements in the figures are illustrated for simplicity and clarity and have not necessarily been drawn to scale. For example, the relative size of some of the elements in the figures may be exaggerated relative to other elements to help improve understanding of illustrated examples of the present disclosure.

### DETAILED DESCRIPTION OF EXEMPLARY EXAMPLES

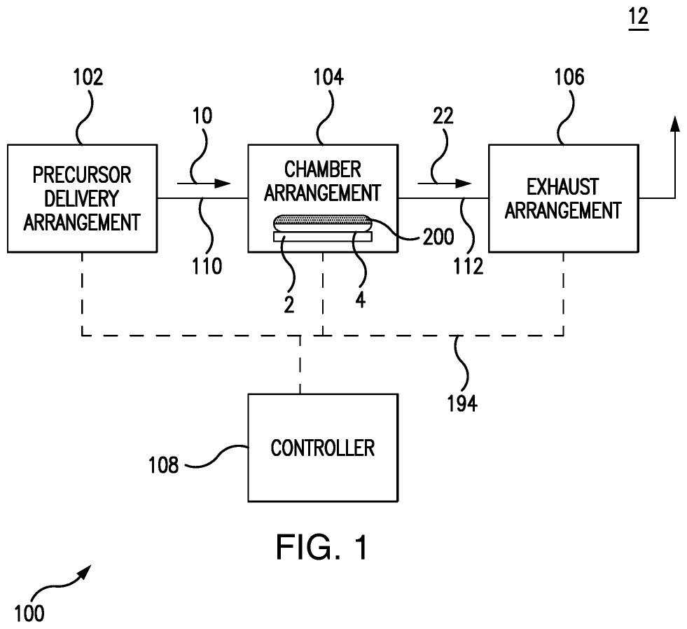

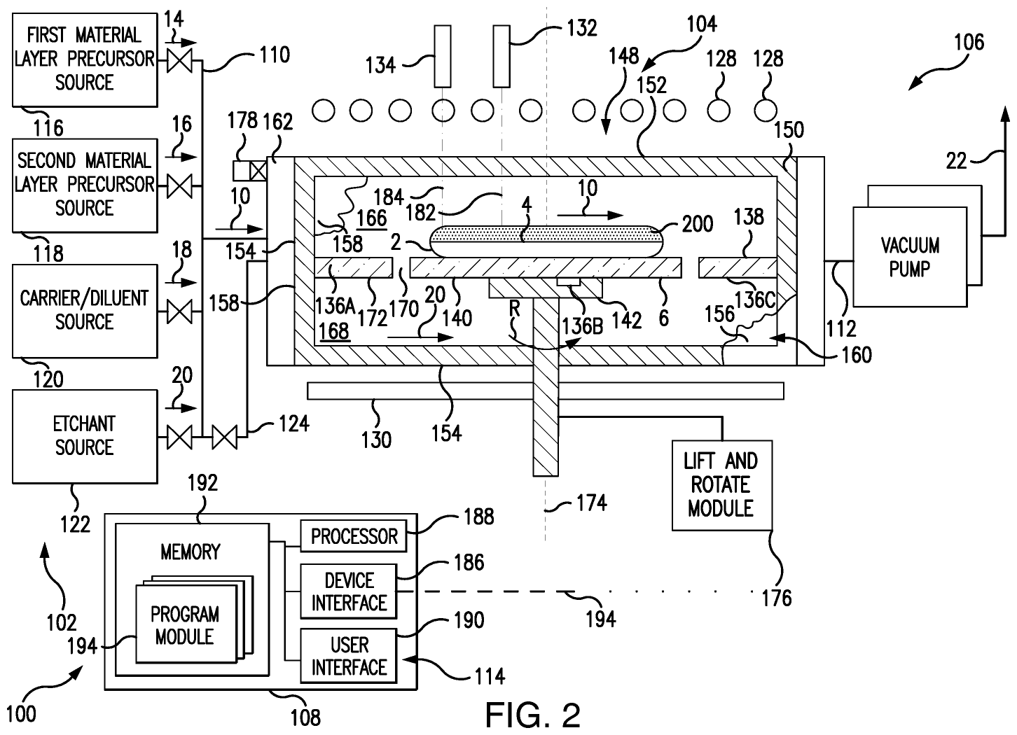

Reference will now be made to the drawings wherein like reference numerals identify similar structural features or aspects of the subject disclosure. For purposes of explanation and illustration, and not limitation, a partial view of a semiconductor processing system in accordance with the present disclosure is shown in FIG. 1 and is designated generally by reference character 100. Other examples of semiconductor processing systems, material layer stacks, material layer deposition methods, and computer program products in accordance with the present disclosure, or aspects thereof, are provided in FIGS. 2-9, as will be described. The systems and methods of the present disclosure may be used to deposit material layers onto substrates, such as silicon-germanium and silicon material layer stacks used to fabricate 3D DRAM semiconductor devices, though the present disclosure is not limited to any particular type of semiconductor device or type material layer stacks in general.

The present disclosure will be described with respect to particular examples and with reference to certain drawings. However, the disclosure is not limited thereto but only by the claims. The drawings described are only schematic and are non-limiting. The dimensions do not correspond to actual reductions to practice the disclosure. The size of some of the elements may not be drawn to scale, in the drawings, for illustrative purposes.

The terms first, second, third and the like appearing in the description and the claims, are there to help in distinguishing between similar elements or similar features. Thus, they are not used necessarily for describing an order or a sequence in any manner. It is to be understood that such terms can be interchangeable under suitable conditions. It is thus, further to be understood that the examples of the disclosure described in the description are capable of being used in other sequences than the described ones.

Reference throughout the specification to “some examples” or “certain examples” means that a particular structure, feature operation described in connection with these examples is included in some of the examples of the present disclosure. Thus, phrases appearing such as “in some examples” in different places throughout the specification are not necessarily referring to the same collection of examples, but may.

As used herein, the term “substrate” refers to any material having a surface onto which material can be deposited. A substrate may include a bulk material such as silicon (e.g., single crystal silicon) or may include one or more layers overlaying the bulk material. Further, the substrate may include various topologies, such as trenches, vias, lines, and the like formed within or on at least a portion of a layer of the substrate.

As used herein and unless provided otherwise, the term “one and only one” refers to the processing of a single substrate at a time, in the absence of other substrates, in a chamber arrangement. Some examples described herein include some but not other features included in other examples. However, combinations of features of different examples are meant to be within the scope of the disclosure, and form different examples, as would be understood by those in the art. In the claims included, any of the claimed examples can, for example, be used in any combination.

Referring to FIG. 1, the semiconductor processing system 100 is shown. The semiconductor processing system 100 includes a precursor delivery arrangement 102, a chamber arrangement 104, an exhaust arrangement 106, and a controller 108. The precursor delivery arrangement 102 is connected to the chamber arrangement 104 by a precursor conduit 110 and is configured to provide a material layer precursor 10 to the chamber arrangement 104. The chamber arrangement 104 is in turn connected to the exhaust arrangement 106 by an exhaust conduit 112 and is configured to support a substrate 2 during deposition of a material layer stack 200 onto an upper surface 4 of the substrate 2. The exhaust arrangement 106 is in turn communication with the external environment 12 outside of the semiconductor processing system 100, is configured to communicate a flow or residual precursor and/or reaction products 22 issued by the chamber arrangement 104 to the external environment 12, and may include one or more of a vacuum pump and an abatement apparatus.

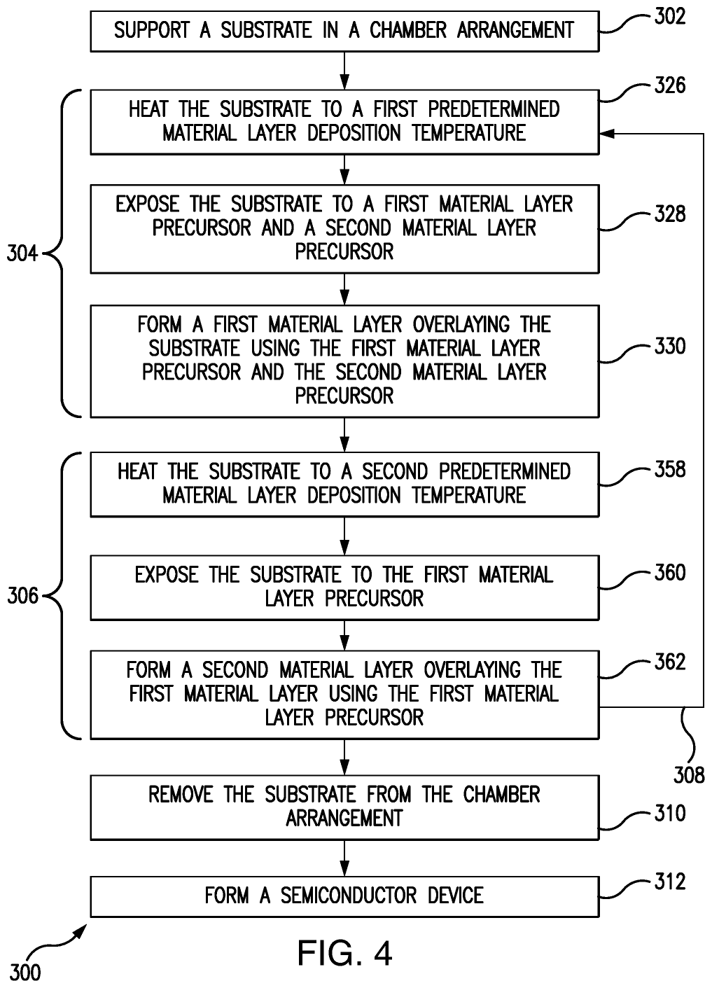

The controller 108 is operably connected to the precursor delivery arrangement 102, the chamber arrangement 104, and/or the exhaust arrangement 106. The controller 108 is further configured to form the material layer stack 200 onto the substrate 2 using a material layer deposition method, e.g., the material layer deposition method 300 (shown in FIGS. 4-6), as will be described. The controller 108 further includes (or is in communication with) a computer program product, e.g., a computer program product 114 (shown in FIG. 2), to perform operations of the material layer deposition method 300 to form the material layer stack 200, as will also be described. Although shown and described herein as a single-substrate cross flow process chamber, it is to be understood and appreciated that semiconductor processing systems having other arrangements may also benefit from the present disclosure.

With reference to FIG. 2, the semiconductor processing system 100 is shown according to an example of the present disclosure. In the illustrated example the precursor delivery arrangement 102 includes a first material layer precursor source 116, a second material layer precursor source 118, a carrier/diluent fluid source 120, and an etchant source 122. The first material layer precursor source 116 includes a first material layer precursor 14 (e.g., a silicon-containing material layer precursor), is connected to the chamber arrangement 104 by the precursor conduit 110, and is configured to provide the first material layer precursor 14 to the chamber arrangement 104 through the precursor conduit 110 via the material layer precursor 10. In certain examples the first material layer precursor 14 may include (e.g., consist of or consist essentially of) trisilane (Si₃H₈). In accordance with certain examples, the first material layer precursor 14 may include tetrasilane (Si₄H₁₀). The second material layer precursor source 118 is similar the first material layer precursor source 116 and additionally includes a second material layer precursor 16 (e.g., a germanium-containing material layer precursor), which may include (e.g., consist of or consist essentially of) germane (GeH₄). It is also contemplated that the second material layer precursor may include another germanium-containing material layer precursor, for example a high order germanium-containing material layer precursor, and remain within the scope of the present disclosure.

The carrier/diluent fluid source 120 includes a carrier/diluent fluid 18, is connected to the chamber arrangement 104 by the precursor conduit 110, and is configured to co-flow the carrier/diluent fluid 18 to the chamber arrangement 104 through the precursor conduit 110 (e.g., via the material layer precursor 10) with the first material layer precursor 14 and/or the second material layer precursor 16. In certain examples, the carrier/diluent fluid 18 may include (e.g., consist of or consist essentially of) an inert gas, such as nitrogen (N₂) gas or a noble gas such as argon (Ar), xenon (Xe), helium (He), or krypton (Kr). In accordance with certain examples, the carrier/diluent fluid 18 may include (e.g., consist of or consist essentially of) hydrogen (H₂) gas. It is also contemplated that the carrier/diluent fluid 18 may include a mixture of the aforementioned materials and remain within the scope of the present disclosure.

The etchant source 122 includes an etchant fluid 20 and is configured to the provide the etchant fluid 20 to the chamber arrangement 104. In certain examples, the etchant source 122 may be connected to the chamber arrangement 104 by the precursor conduit 110 and configured to the provide the etchant fluid 20 to the chamber arrangement 104 using the precursor conduit 110 (e.g., via the material layer precursor 10). In accordance with certain examples, the etchant source 122 may be connected to the chamber arrangement 104 by an etchant conduit 124 to provide the etchant fluid 20 the chamber arrangement 104 as a lower chamber purge flow, for example, to etch a lower surface 6 of the substrate 2 during deposition of the material layer stack 200 onto the upper surface 4 of the substrate 2. It is contemplated that etchant include a halide-containing material. In this respect the etchant fluid 20 may include chlorine (Cl), which may be provided to the chamber arrangement 104 as chlorine (Cl₂) gas and/or hydrochloric acid (HCl). The etchant fluid 20 may alternatively (or additionally) include fluorine (F). In such examples the etchant fluid 20 may be provided to the chamber arrangement 104 as fluorine (F₂) gas and/or hydrogen fluoride (HF) by way of non-limiting examples.

The chamber arrangement 104 includes a chamber body 126, an upper heater element array 128, and a lower heater element array 130. The chamber arrangement 104 also includes a first non-contact temperature sensor 132, a second non-contact temperature sensor 134, and the contact temperature sensors 136A-136C. In the illustrated example the chamber arrangement 104 further includes a divider 138, a substrate support 140, a support member 142, and a shaft member 144. As will be appreciated by those of skill in the art in view of the present disclosure, the chamber arrangement 104 may include other elements and/or omit certain elements shown and described herein in other examples of the present disclosure and remain within the scope of the present disclosure.

The chamber body 126 extends between an injection end 146 and a longitudinally opposite exhaust end 148 and is formed from a transparent material 150. The chamber body 126 further has an upper wall 152, a lower wall 154, a first sidewall 156, and a second sidewall 158. The upper wall 152 extends longitudinally between the injection end 146 and the exhaust end 148 of the chamber body 126. The lower wall 154 also extends between the injection end 146 and the exhaust end 148 of the chamber body 126 and is further spaced apart from the upper wall 152 by an interior 160 of the chamber body 126. The first sidewall 156 and the second sidewall 158 couple the upper wall 152 to the lower wall 154 of the chamber body 126 and are spaced apart from one another by the interior 160 of the chamber body 126. It is contemplated that an injection flange 162 abut the injection end 146 of the chamber body 126, an exhaust flange 164 abut the exhaust end 148 of the chamber body 126, that the injection flange 162 connect the precursor conduit 110 and an etchant conduit 124 to the chamber body 126, and that the exhaust flange 164 couple the exhaust arrangement 106 to the chamber body 126. In certain examples, the transparent material 150 forming the chamber body 126 may be a ceramic material. Examples of suitable ceramic materials include quartz and sapphire. In accordance with certain examples, the chamber body may have a plurality of exterior ribs extending laterally about the chamber body 126 and longitudinally spaced apart from one another between the injection end 146 and the exhaust end 148 of the chamber body 126. Although shown and described herein as being flat, it is to be understood and appreciated that either (or both) the upper wall 152 and/or the lower wall 154 may have an arcuate dome-like profile and remain within the scope of the present disclosure.

The divider 138 is fixed within the interior 160 of the chamber body 126 and divides the interior 160 of the chamber body 126 into an upper chamber 166 and a lower chamber 168. The divider 138 further defines an aperture 170 extending therethrough, the aperture 170 fluidly coupling the lower chamber 168 to the upper chamber 166 of the chamber body 126. The divider 138 may be further formed from an opaque material 172, for example, a material opaque to infrared electromagnetic radiation. Examples of suitable opaque materials include silicon carbide and carbonaceous materials, such as silicon carbide-coated graphite. In certain examples, one or more contact temperature sensors, e.g., an upstream contact temperature sensor 136A and a downstream contact temperature sensor 136C, may be in contact with the divider and in thermal communication therethrough with the interior 160 of the chamber body 126.

The substrate support 140 is arranged within the interior 160 of the chamber body 126, is supported for rotation R within the aperture 170 about a rotation axis 174, and is configured to support thereon the substrate 2 during deposition of a material layer stack 200 thereon. The support member 142 is arranged within the lower chamber 168 of the chamber body 126, and along the rotation axis 174 and is fixed in rotation relative to the substrate support 140. The shaft member 144 is fixed in rotation relative to the support member 142, extends through the lower wall 154 of the chamber body 126, and operably connects the substrate support 140 to a lift and rotate module 176. The lift and rotate module 176 is configured to rotate the substrate support 140 about the rotation axis 174 during deposition of the material layer stack 200 onto the substrate 2. It is also contemplated that the lift and rotate module 176 be configured to seat and unseat the substrate 2 from the substrate support 140 prior to and subsequent to deposition of the material layer stack 200 onto the substrate 2. In this respect the lift and rotate module 176 may cooperate with a gate valve 178 connected to the injection flange 162 and a substrate transfer robot 180 to load and unload substrates from the chamber body 126. In certain examples, the substrate support 140 may include a susceptor body. In accordance with certain examples, the substrate support 140 may be formed from an opaque, for example, the opaque material 172. It is also contemplated that one or more of the support member 142 and the shaft member 144 may be formed from a transmissive material, e.g., the transparent material 150.

The upper heater element array 128 includes a plurality of heater elements each supported above the upper wall 152 of the chamber body 126 and configured to radiantly heat the substrate 2 using electromagnetic radiation communicated through the transparent material 150 forming the upper wall 152. In certain examples, the upper heater element array 128 may include one or more linear filament-type lamps. In such examples the one or more linear filament-type lamps may extend laterally across the chamber body 126 and in parallel with one another, the one or more linear filament-type lamps longitudinally spaced apart from one another between the injection flange 162 and the exhaust flange 164. In accordance with certain examples, the upper heater element array 128 may include one or more bulb-type heater elements and remain within the scope of the present disclosure. The lower heater element array 130 is similar to the upper heater element array 128, is additionally supported below the lower wall 154 of the chamber body 126, may include a plurality of linear lamps extending longitudinally between the injection end 146 and the exhaust end 148 of the chamber body 126, and may further include one or more spot-type lamps distributed circumferentially about the rotation axis 174 and oriented toward the shaft member 144. It is contemplated that lower heater element array 130 be configured to heat the substrate 2 (shown in FIG. 1) radiantly using electromagnetic radiation transmitted through the lower wall 154 of the chamber body 126 and incident upon the opaque material 172 forming the substrate support 140.

The first non-contact temperature sensor 132 is optically coupled to the interior 160 of the chamber body 126 by the transparent material 150 forming the upper wall 152 of the chamber body 126 and is configured to optically acquire a first temperature measurement from within the chamber body 126. In this respect the first non-contact temperature sensor 132 is supported above the upper heater element array 128 along a first optical axis 182 extending between heater elements of the upper heater element array 128, the first optical axis 182 substantially orthogonal relative the upper wall 152 of the chamber body 126, and proximate to the rotation axis 174. It is contemplated that the first non-contact temperature sensor 132 be optically coupled to an upper surface 4 of the substrate 2, or the material layer stack 200 during deposition thereon, and configured to acquire a first temperature of the substrate 2 during deposition of the material layer stack 200 thereon. The second non-contact temperature sensor 134 is similar to the first non-contact temperature sensor 132, is additionally arranged along a second optical axis 184, and is further configured to optically acquire a second temperature measurement from within the chamber arrangement 104. In this respect the second optical axis 184 is radially offset from the first optical axis 182, the first optical axis 182 radially between the second optical axis 184 and the rotation axis 174, the second optical axis 184 intersecting the upper surface 4 of the substrate 2 (or the material layer stack 200 during deposition thereon) at a location radially outward of the first optical axis 182. In certain examples, the first non-contact temperature sensor 132 and/or the second non-contact temperature sensor 134 may include a pyrometer. In accordance with certain examples, the first non-contact temperature sensor 132 and/or the second non-contact temperature sensor 134 may cooperate with a chamber wall non-contact temperature, e.g., a quartz pyrometer. It is also contemplated that the first non-contact temperature sensor 132 and/or the second non-contact temperature sensor 134 may cooperate with a third non-contact temperature sensor arranged radially along a third optical axis radially intermediate the first optical axis 182 and the second optical axis 184.

The contact temperature sensors 136A-136C are arranged within the interior 160 of the chamber body 126 and are configured to acquire tactile temperature measurements from within the interior 160 of the chamber body 126. In this respect contact temperature sensors 136A and 136C are in contact with the divider 138 (e.g., seated therein), the forward contact temperature sensor 136A in contact with the divider 138 at a location upstream of the substrate support 140 relative to the general direction of flow between the injection flange 162 and the exhaust flange 164, the rear contact temperature sensor 136C in contact with the divider 138 at a location downstream of the substrate support 140. The substrate support contact temperature sensor 136B is further in contact with the substrate support 140 and at a location longitudinally between the contact temperature sensor 136A and the contact temperature sensor 136C. In this respect the contact temperature sensor 136C may be fixed in rotation relative to the substrate support 140 to inferentially acquire temperature of the material layer stack 200. In further respect, the contact temperature sensor 136A is in contact with the divider 138 to inferentially acquire temperature of the material layer precursor 10 as the material layer precursor 10 flows toward the substrate 2 and prior the material layer precursor 10 arriving at the substrate 2. In certain examples, one or more of the contact temperature sensors 136A-136C may include a thermocouple.

The controller 108 includes a device interface 186, a processor 188, a user interface 190, and a memory 192. The device interface 186 connects the processor 188 to a wired or wireless link 194 and therethrough to the chamber arrangement 104. In certain examples, the device interface 186 may operably connect the lift and rotate module 176, the upper heater element array 128, and/or the lower heater element array 130 through the wired or wireless link 194. In accordance with certain examples, the device interface 186 may provide communication between one or more of the contact temperature sensors 136A-136C, the first non-contact temperature sensor 132, and/or the second non-contact temperature sensor 134 with the processor 188 to the wired or wireless link 194. It is also contemplated that, in accordance with certain examples, the device interface 186 may operably connect the processor 188 to one or more of the gate valve 178, the substrate transfer robot 180, the precursor delivery arrangement 102, and/or the exhaust arrangement 106 through the wired or wireless link 194.

The processor 188 is operably connected to the user interface 190 and disposed in communication with the memory 192. The memory 192 includes a non-transitory machine-readable medium having a plurality of program modules recorded thereon that, when read by the processor 188, cause the processor 188 to execute certain operations. Among the operations are operations of a material layer deposition method 300 (shown in FIG. 4), as will be described. Although shown and described herein as having a specific architecture, it is to be understood and appreciated that other computing architectures are possible, e.g., distributed computing architectures, and remain within the scope of the present disclosure. In this respect the memory 192 may comprise a computer program product, e.g., the computer program product 114, with instruction recorded thereon for depositing the material layer stack 200 onto the substrate 2.

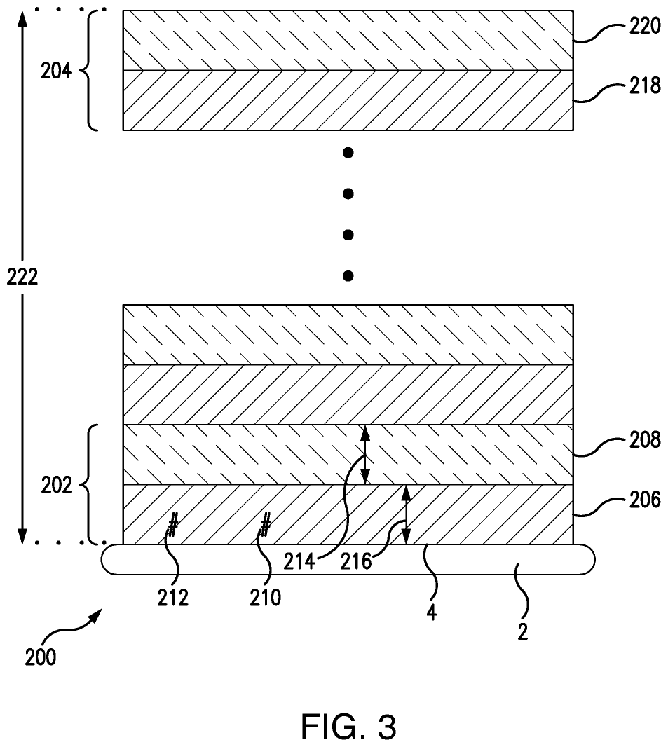

With reference to FIG. 3, the material layer stack 200 is shown. The material layer stack 200 includes a first material layer pair 202 and one or more second material layer pair 204. The first material layer pair 202 includes a first silicon-germanium material layer 206 and a first silicon material layer 208. The first silicon-germanium material layer 206 overlays the substrate 2, is epitaxial in structure with respect to the substrate 2, and is deposited directly onto the upper surface 4 of the substrate 2. The first silicon material layer 208 overlays the first silicon-germanium material layer 206, is epitaxial in structure with respect to a crystalline structure of the first silicon-germanium material layer 206, and is deposited directly onto the first silicon-germanium material layer 206.

In certain examples, the first silicon-germanium material layer 206 may have a germanium concentration 210 that is between about 10 atomic % to and about 30 atomic %. For example, the germanium concentration 210 may be between about 10 atomic % and about 15 atomic %, or between about 15 atomic % and about 20 atomic %, or between about 20 atomic % and about 25 atomic %, or even between about 25 atomic % and about 30 atomic %. The first silicon-germanium material layer 206 may have a silicon concentration 212 that is between about 70 atomic % and about 90 atomic %. For example, the silicon concentration 212 may be between about 70 atomic % and about 75 atomic %, or between about 75 atomic % and about 80 atomic %, or between about 80 atomic % and about 85 atomic %, or even between about 85 atomic % and about 90 atomic %. As will be appreciated by those of skill in the art in view of the present disclosure, silicon-germanium material layers having germanium and/or silicon concentrations within these ranges facilitates fabrication of semiconductor devices from the material layer stack 200, for example, by imparting etch selectivity into the silicon-germanium material layers relative to the silicon material layers forming the material layer stack 200.

In certain examples, the first silicon-germanium material layer 206 may have a silicon-germanium material layer thickness 214 that is less than 25 nanometers. For example, the first silicon-germanium material layer thickness 214 may be between about 25 nanometers and about 5 nanometers. The silicon-germanium material layer thickness 214 may be between about 25 nanometers and about 20 nanometers, or between about 20 nanometers and about 15 nanometers, or between about 15 nanometers and about 10 nanometers, or between about 10 nanometers and about 5 nanometers. In accordance with certain examples, the first silicon-germanium material layer 206 may have a within-material layer thickness variation that is less than 1 nanometer, for example, that is between about 1 nanometer and about 0.2 nanometers. In this respect it is contemplated that the first silicon-germanium material layer 206 may have a thickness that is between about 1 nanometer and about 0.8 nanometers, or between about 0.8 nanometers and about 0.6 nanometers, or between about 0.6 nanometers and about 0.4 nanometers, or even between about 0.4 nanometers and about 0.2 nanometers. As will be appreciated by those of skill in the art in view of the present disclosure, silicon-germanium material layers having thicknesses and within-material layer thickness variation within these ranges enable device densities greater than otherwise possible for the device architecture, limiting cost of such devices.

In certain examples, the first silicon material layer 208 may have a silicon material layer thickness 216 that is less about 100 nanometers, for example between about 100 nanometers and about 20 nanometers. In certain embodiments of the present disclosure the silicon material layer thickness 216 may be between about 100 nanometers and about 80 nanometers, or between about 80 nanometers and about 60 nanometers, or between about 60 nanometers and about 40 nanometers, or even between about 40 nanometers and about 20 nanometers. The first silicon material layer 208 may have a within-material layer thickness variation that is less than 2 nanometers, for example, between about 2 nanometers and about 0.4 nanometers. In certain examples of the present disclosure the first silicon material layer 208 may have a within-material layer thickness variation that is between about 2 nanometers and about 0.4 nanometers, or between about 2 nanometers and about 1.6 nanometers, or between about 1.6 nanometers and about 1.2 nanometers, or between about 1.2 nanometers and about 0.8 nanometers, or even between about 0.8 nanometers and about 0.4 nanometers. As will also be appreciated by those of skill in the art in view of the present disclosure, silicon material layers having thicknesses and within-material layer variation in these ranges also enable greater device density than otherwise possible, limiting device cost of such devices.

The one or more second material layer pair 204 is similar to the first material layer pair 202 and includes a second silicon-germanium material layer 218 and a second silicon material layer 220. The second silicon-germanium material layer 218 is similar to the first silicon-germanium material layer 206, additionally overlays the first silicon material layer 208, and is epitaxial in structure relative to the crystalline structure of the first silicon material layer 208. The second silicon material layer 220 is similar to the first silicon material layer 208, is additionally deposited directly onto the second silicon-germanium material layer 218, and is epitaxial in structure with respect to a crystalline structure of the second silicon-germanium material layer 218.

In certain examples the material layer stack 200 may be have more than 20 material layer pairs, for example, between 20 material layer pairs and 400 material layer pairs, such as between 20 material layer pairs. In certain examples of the present disclosure the material layer stack 200 may have between 20 material layer pairs and 96 material layer pairs, or between 96 material layer pairs and 172 material layer pairs, or between 172 material layer pairs and 248 material layer pairs, or between 248 material layer pairs and 324 material layer pairs, or even between 324 material layer pairs and 400 material layer pairs. In accordance with certain examples, material layer stack 200 may have a stack thickness 222 that is greater than 5 microns, for example, between about 5 microns and about 11 microns. In certain examples of the present disclosure the stack thickness 222 may be between about 5 microns and about 7 microns, or between about 7 microns and about 9 microns, or even between about 9 microns and about 11 microns In certain examples, the silicon-germanium material layers forming the material layer stack may have a layer-to-layer thickness variation (three sigma) that is less than about 2 nanometers, for example, between about 2 nanometers and about 0.5 nanometers. In certain examples of the present disclosure the layer-to-layer thickness variation of the silicon-germanium material layers forming the material layer stack 200 may be between about 2 nanometers and about 1.5 nanometers, or between about 1.5 nanometers and about 1 nanometer, or even between about 1 nanometer and about 0.5 nanometers. In accordance with certain examples, the silicon material layers forming the material layer stack 200 may have a layer-to-layer thickness variation (three sigma) that is less than about 10 nanometers, for example, is between about 10 nanometers and about 2 nanometers. In certain examples of the present disclosure the silicon material layers forming the material layer stack 200 may have a layer-to-layer thickness variation that is between about 10 nanometers and about 8 nanometers, or between about 8 nanometers and about 6 nanometers, or between about 6 nanometers and about 4 nanometers, or even between about 4 nanometers and about 2 nanometers. Advantageously, the material layer stacks having layer-to-layer variation within these ranges may be employed to fabricate semiconductor devices having both high device density and reliable electrical performance.

With reference to FIGS. 4-7, the material layer deposition method 300 is shown. As shown in FIG. 4, the material layer deposition method 300 includes supporting a substrate within a chamber arrangement, e.g., supporting the substrate 2 (shown in FIG. 1) in the chamber arrangement 104 (shown in FIG. 1), as shown with box 302. The material layer deposition method 300 also includes depositing a first material layer onto the substrate, e.g., the first silicon-germanium material layer 206 (shown in FIG. 3), and depositing a second material layer onto the first material layer, e.g., the first silicon material layer 208 (shown in FIG. 3), as shown with bracket 304 and bracket 306. It is contemplated that the first material layer and the second material layer may be a first material layer pair, e.g., the first material layer pair 202 (shown in FIG. 3), and that the material layer deposition method 300 further include depositing one or more second material layer pair onto the first material layer pair to form a material layer stack, e.g., the second material layer pair 204 (shown in FIG. 3) deposited onto the first material layer pair to form the material layer stack 200 (shown in FIG. 1), as shown with arrow 308. It is also contemplated that the substrate may then be removed from the chamber arrangement and sent on for further processing, as shown with box 310, and a semiconductor device be formed using the first material layer pair and the second material layer pair, as shown with box 312.

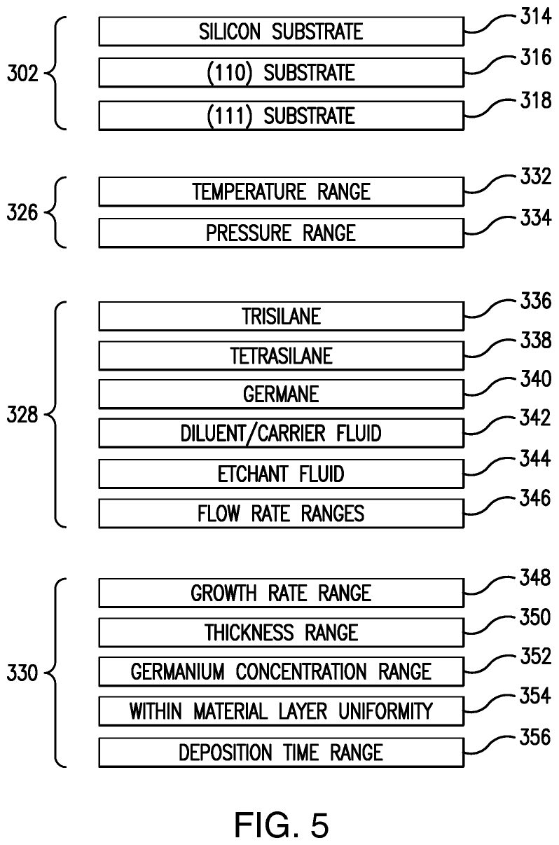

As shown in FIG. 5, supporting 302 the substrate within the chamber arrangement may include support a silicon substrate within the chamber arrangement, such as a silicon wafer, as shown with box 314. In certain examples, supporting 302 the substrate within the chamber arrangement may include supporting a substrate having a (111) crystalline structure within the chamber arrangement, as shown with box 316. In accordance with certain examples, supporting 302 the substrate within the chamber arrangement may include a substrate having a (110) crystalline structure within the chamber arrangement, as shown with box 318. It is contemplated that, in certain examples, crystalline structure may be presented to an interior of the chamber arrangement, e.g., to the upper chamber 166 (shown in FIG. 2) of the chamber body 126 (shown in FIG. 2), for deposition of the material layer stack onto the upper surface of the substrate. It is also contemplated that the crystalline structure may be unitary, e.g., a blanket crystalline structure defined substantially the entirety of the surface onto which the material layer stack is formed. It is further contemplated that upper surface of the substrate may define more than one crystalline structure, e.g., within a trench defined within the upper surface of the substrate, and remain within the scope of the present disclosure.

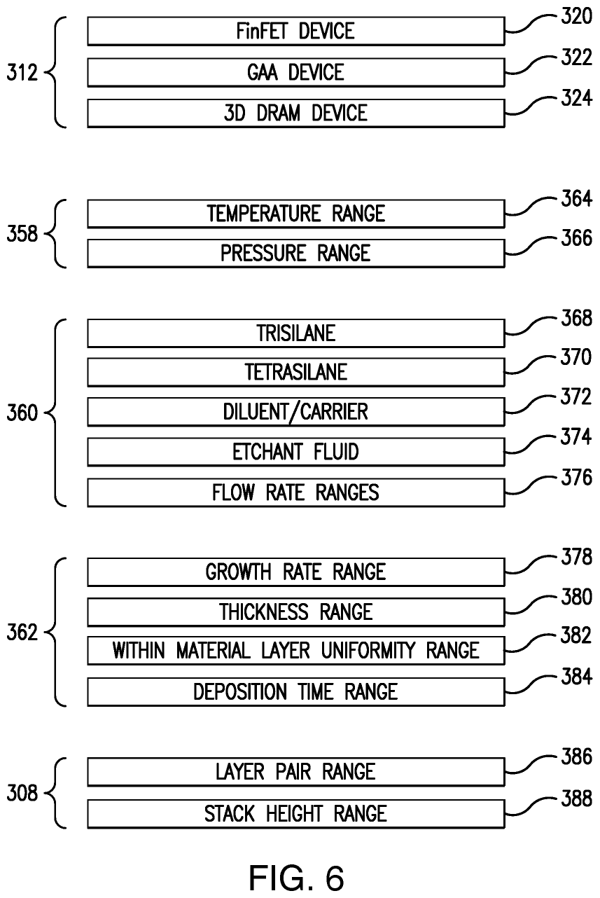

As shown in FIG. 6, forming 312 the semiconductor device may include forming a FinFET semiconductor device on the upper surface of the substrate using the material layer stack, as shown with box 320. Forming 312 the semiconductor device may include forming a gate-all-around semiconductor device on the upper surface of the substrate using the material layer stack, as shown with box 322. Forming 312 the semiconductor device may include forming a 3D DRAM device on the upper surface of the substrate using the material layer stack, as shown with box 324. It is also contemplated that other types of semiconductor devices, e.g., semiconductor devices having other three-dimensional architectures and/or device scaling features, may be formed on the upper surface of the substrate using the material layer stack and remain within the scope of the present disclosure.

With continuing reference to FIG. 4, depositing 304 the first material layer pair onto the substrate includes heating the substrate to a first predetermined material layer deposition temperature, as shown with box 326. Depositing 304 the first material layer pair onto the substrate also includes exposing the substrate to a first material layer precursor and a second material layer precursor, e.g., the silicon-containing material layer precursor and the germanium-containing material layer precursor, as shown with box 328. Depositing 304 the first material layer pair further includes forming a first material layer, e.g., the first silicon-germanium material layer 206 (shown in FIG. 3), using the first material layer precursor and the second material layer precursor, as shown with box 330.

Referring once again to FIG. 5, heating 326 the substrate to the first predetermined material layer deposition temperature may include heating the substrate to a predetermined first deposition temperature that is less than 800 degrees Celsius, for example between about 800 degrees Celsius and about 500 degrees Celsius, as shown with box 332. In certain examples of the present disclosure the substrate may be heated to between about 500 degrees Celsius and about 800 degrees Celsius, or to between about 550 degrees Celsius and about 600 degrees Celsius, or to between about 600 degrees Celsius and about 650 degrees Celsius. The substrate may be heated to between about 650 degrees Celsius and about 700 degrees Celsius, or between about 700 degrees Celsius and about 750 degrees Celsius, or even to between about 750 degrees Celsius and about 800 degrees Celsius. Heating 326 may be accomplished, for example, using an upper heater element array and/or a lower heater element array, e.g., the upper heater element array 128 (shown in FIG. 2) and the lower heater element array 130 (shown in FIG. 2), as also shown with box 332.

Heating 326 the substrate may include evacuating an interior of the chamber arrangement, e.g., the interior 160 (shown in FIG. 2) of the chamber body 126 (shown in FIG. 2), as shown with box 334. In this respect the chamber body may be evacuated to a first material layer deposition pressure that is less than about 50 Torr, for example between about 50 Torr and about 1 Torr, as also shown with box 334. In certain examples of the present disclosure the chamber body may be evacuated to a first material layer deposition pressure between about 50 Torr and about 40 Torr, or between about 40 Torr and about 30 Torr, or between about 30 Torr and about 20 Torr. The chamber body may be evacuated to a first material layer deposition pressure that is between about 20 Torr and about 10 Torr or even between about 10 Torr and about 1 Torr. Evacuation may be accomplished, for example, using a vacuum pump included in an exhaust arrangement, e.g., the exhaust arrangement 106 (shown in FIG. 1), as further shown with box 334.

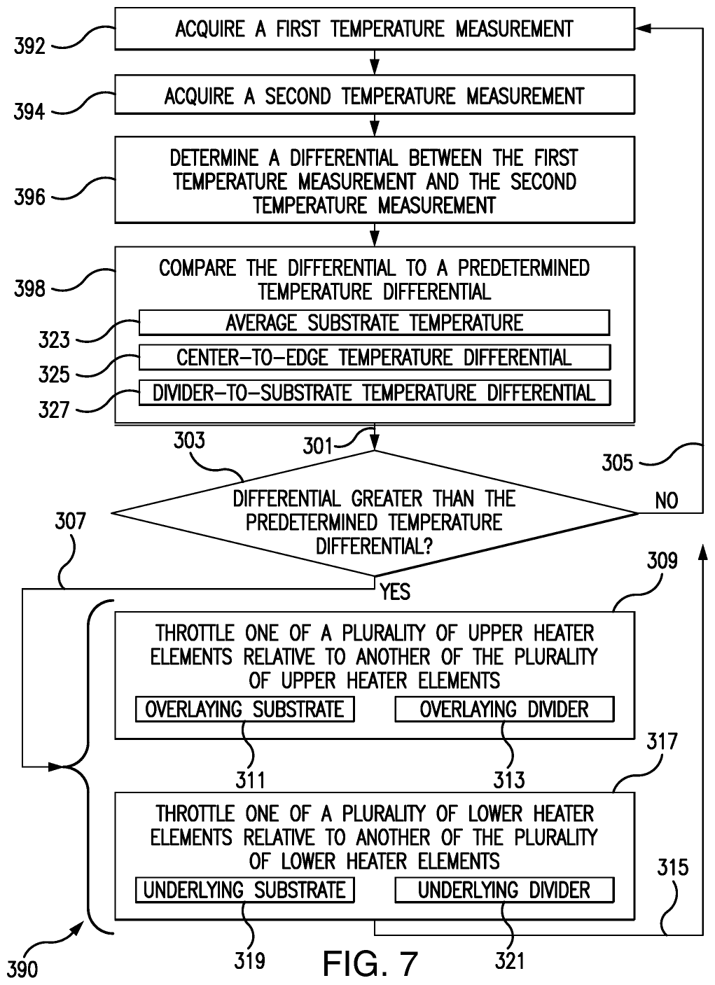

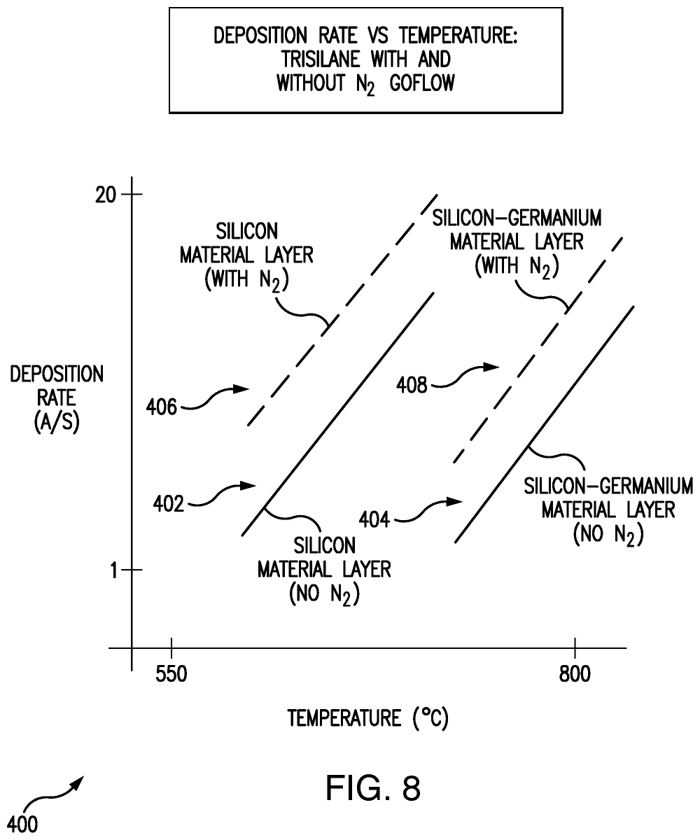

Exposing 328 the substrate to the first material layer precursor and the second material layer precursor may include exposing the substrate to a silicon-containing material layer precursor, e.g., the first material layer precursor 14 (shown in FIG. 2), as shown with bracket 328. The first material layer precursor may have a general molecular formula of SiₙH₂ₙ₊₂ where n is an integer from at least 1 to at most 20, such as a mono silane or a high order silane. For example, the first material layer precursor may include e.g., consist of or consist essentially of) trisilane (Si₃H₈), as shown with box 336. Alternatively, the first material layer precursor may include (e.g., consist of or consist essentially of tetrasilane (Si₄H₁₀), as shown with box 338. It is also contemplated that the first material layer precursor may include a plurality of silicon-containing materials, e.g., trisilane (Si₃H₈) and tetrasilane (Si₄H₁₀), and remain within the scope of the present disclosure. Advantageously, as shown in FIGS. 7 and 8, forming the material layer stack using trisilane (Si₃H₈) and tetrasilane (Si₄H₁₀) may provide relatively high throughput due to the deposition rates associated with trisilane (Si₃H₈) and tetrasilane (Si₄H₁₀) at temperatures employed in single-substrate processing regimes.

Exposing 328 the substrate to the first material layer precursor and the second material layer precursor may include exposing the substrate to a germanium-containing material layer precursor, as shown with bracket 328. In this respect the second material layer precursor may include (e.g., consist of or consist essentially of) germane (GeH₄), as shown with box 340. In certain examples, the second material layer precursor may include a high order germanium-containing material layer precursor, as also shown with box 340. For example, the germanium-containing material layer precursor may include one or more of di-germane (Ge₂H₆), tri-germane (Ge₃H₈), tetra-germane (Ge₄H₁₀), a germane having a general molecular formula of GeₓH₂ₓ₊₂ and remain within the scope of the present disclosure.

Exposing 328 the substrate to the first material layer precursor and the second material layer precursor may include co-flowing a carrier/diluent fluid, e.g., the carrier/diluent fluid 18 (shown in FIG. 1), with the first material layer precursor and the second material layer precursor, as shown with box 342. The carrier/diluent fluid may include an inert gas such as nitrogen (N₂) gas or a noble gas such as argon (Ar), krypton (Kr), helium (He), and xenon (Xe). The carrier/diluent fluid may include hydrogen (H₂) gas, as further shown with box 340. It is also contemplated that no carrier/diluent fluid may be co-flowed with the first material layer precursor and the second material layer precursor, or that a mixture including one or more of the aforementioned diluent/carrier fluids may be co-flowed with the first material layer precursor and the second material layer precursor and remain within the scope of the present disclosure. Advantageously, as shown in FIGS. 7 and 8, co-flowing nitrogen (N₂) gas with silicon-containing material precursors such as trisilane (Si₃H₈) and tetrasilane (Si₄H₁₀) may increase deposition rate of the first material layer, increasing throughput of semiconductor processing systems employed for the material layer deposition method 300.

Exposing 328 the substrate to the first material layer precursor and the second material layer precursor may include exposing the substrate to an etchant fluid, e.g., the etchant fluid 20 (shown in FIG. 1), as shown with box 344. The etchant fluid may include a halogen-containing material, such as chlorine (Cl₂) gas and/or hydrochloric acid (HCl). The etchant fluid may be co-flowed with the first material layer precursor and the second material layer precursor such that the upper surface of the substrate is exposed to the etchant fluid. The etchant fluid may be introduced into a lower chamber of the chamber body, e.g., the lower chamber 168 (shown in FIG. 2) of the chamber body 126 (shown in FIG. 2), and communicated therethrough to the lower surface of the substrate, as also shown with box 344. It is also contemplated that the etchant fluid may be introduced into both the upper chamber and the lower chamber of the chamber body, and therethrough to the upper surface and the lower surface of the substrate, and remain within the scope of the present disclosure. As will be appreciated by those of skill in the art in view of the present disclosure, providing etchant to the lower surface of the substrate may limit (or eliminate) formation of backside deposition on the substrate, which can be employed to relieve stress within the material layer stack otherwise associated with chamber arrangements employing substrate edge support techniques.

Exposing 328 the substrate to the first material layer precursor and the second material layer precursor may include flowing the first material layer precursor into the chamber body at a first material layer precursor flow rate, as shown with box 346. The first material layer precursor flow rate may be between about 25 milligrams per minute and about 275 milligrams per minute. In this respect the first material layer precursor flow rate may be between about 25 milligrams per minute and about 75 milligrams per minute, or between about 75 milligrams per minute and about 125 milligrams per minute, or even between about 200 milligrams per minute and about 275 milligrams per minute.

Exposing 328 the substrate to the first material layer precursor and the second material layer precursor may include flowing the second material layer precursor into the chamber body at second material layer flow rate, as also shown with box 346. The second material layer flow rate may be between about 20 standard cubic centimeter per minute and about 180 standard cubic centimeter per minute. For example, the second material layer precursor flow rate may be between about 20 standard cubic centimeter per minute and about 60 standard cubic centimeter per minute, or between about 100 standard cubic centimeter per minute and about 140 standard cubic centimeter per minute, or even between about 140 standard cubic centimeter per minute and about 180 standard cubic centimeter per minute. It is contemplated that the second material layer precursor be co-flowed with the first material layer precursor, e.g., via the material layer precursor 10 (shown in FIG. 1), as further shown with bracket 328.

Exposing 328 the substrate to the first material layer precursor and the second material layer precursor may also include flowing the carrier/diluent fluid, and/or the etchant, at a first carrier/diluent fluid flow rate, as additionally shown with box 346. The first carrier/diluent fluid flow rate may be between about 5 standard liters per minute and about 20 standard liters per minute. For example, the first carrier/diluent fluid flow rate may be between about 5 standard liters per minute and about 10 standard liters per minute, or between about 10 standard liters per minute and about 15 standard liters per minute, or even between about 15 standard liters per minute and about 20 standard liters per minute. It is contemplated that the carrier/diluent fluid, and/or the etchant fluid, be co-flowed with the first material layer precursor and the second material layer precursor, e.g., via the material layer precursor 10 (shown in FIG. 1), as also shown with box 346.

Forming 330 the first material layer may include depositing the first material layer at a first material layer deposition rate that is greater than about 12 angstroms per second, for example, between about 12 angstroms per second and about 60 angstroms per second, as shown with box 348. In certain examples of the present disclosure the first material layer deposition rate may be between about 12 angstroms per second and about 24 angstroms per second, or between about 24 angstroms per second and about 36 angstroms per second, or between about 36 angstroms per second and about 48 angstroms per second, or even between about 48 angstroms per second and about 60 angstroms per second, as also shown with box 348. As will be appreciated by those of skill in the art in view of the present disclosure, deposition rates within these ranges may enable throughput in single substrate processing regimes comparable to mini-batch and batch-type process modules.

Forming 330 the first material layer may be accomplished within a first layer deposition interval that is between about 5 seconds and about 40 seconds, as shown with box 356. For example, the first material layer may be deposited during a first material layer deposition interval that is between about 5 seconds and about 12 seconds, or between about 12 seconds and about 19 seconds, or between about 19 seconds and about 26 seconds, as shown with box 356. The first material layer may be deposited during a first material layer deposition interval that is between about 26 seconds and about 33 seconds or even between about 33 seconds and about 40 seconds, as further shown by box 356.

With continuing reference to FIG. 4, depositing 306 the second material layer pair onto the substrate includes heating the substrate to a second predetermined material layer deposition temperature, as shown with box 358. Depositing 306 the second material layer pair onto the substrate also includes exposing the substrate to the first material layer precursor, as shown with box 360. Depositing the second material layer pair onto the substrate further include forming a second material layer onto the substrate, e.g., the first silicon material layer 208 (shown in FIG. 3), as shown with box 362.

Referring to FIG. 6, heating 358 the substrate to the second material layer deposition temperature may be similar to heating the substrate to the first material layer deposition temperature as shown in box 326 and in this respect the second material layer deposition temperature may be between about 500 degrees Celsius and about 800 degrees Celsius, as shown with box 364. The second material layer deposition temperature may be between about 550 degrees Celsius and about 600 degrees Celsius, or to between about 600 degrees Celsius and about 650 degrees Celsius, or between about 650 degrees Celsius and about 700 degrees Celsius, as also shown with box 364. The second material layer deposition temperature may be between about 700 degrees Celsius and about 750 degrees Celsius or even to between about 750 degrees Celsius and about 800 degrees Celsius, as further shown by box 366. In certain examples, the second material layer deposition temperature may be substantially equivalent to the first material layer deposition temperature, improving throughput by limiting (or eliminating) time otherwise required for temperature stabilization following temperature change. In accordance with certain examples, the substrate may remain within the chamber arrangement during deposition of both depositing 304 the first material layer and depositing 304 the second material layer 306, also improving throughput by limiting (or eliminating) time otherwise required for temperature stabilization.

Heating 358 the substrate may maintaining the pressure established during the depositing 304 of the first material layer onto the substrate during depositing 306 the second material layer onto the first material layer and in this respect the chamber body may be evacuated to a second material layer deposition pressure that is between about 50 Torr and about 1 Torr, as shown with box 366. The second material layer deposition pressure may be between about 50 Torr and about 40 Torr, or between about 40 Torr and about 30 Torr, or between about 30 Torr and about 20 Torr, as also shown with box 366. The second material layer deposition pressure may be between about 20 Torr and about 10 Torr or even between about 10 Torr and about 1 Torr, as further shown with box 366. In certain examples, the second material layer deposition pressure may be substantially equivalent to the first material layer deposition pressure, improving throughput by limiting (or eliminating) the need to stabilize pressure within the chamber arrangement following pressure change.

Exposing 360 the substrate to the first material layer precursor during depositing 306 the second material layer may include exposing the first material layer (e.g., the substrate with the first material layer thereon) to the same silicon-containing material layer precursor as during depositing 304 the first material layer, as shown with box 368 and box 370. The first material layer precursor employed to deposit the second material layer may have a general molecular formula of SiₙH₂ₙ₊₂ where n is an integer from at least 1 to at most 20, such as a mono silane or a high order silane. For example, the first material layer precursor employed to deposit the second material layer may include e.g., consist of or consist essentially of) trisilane (Si₃H₈), as shown with box 368. Alternatively, the first material layer precursor employed to deposit the second material layer may include (e.g., consist of or consist essentially of tetrasilane (Si₄H₁₀), as shown with box 370. It is also contemplated that the first material layer precursor employed to deposit the second material layer may also include a plurality of silicon-containing materials, e.g., trisilane (Si₃H₈) and tetrasilane (Si₄H₁₀), and remain within the scope of the present disclosure.

Exposing 360 the substrate to the first material layer precursor during deposition of the second material layer may include co-flowing a carrier/diluent fluid, e.g., the carrier/diluent fluid 18 (shown in FIG. 1), with the first material layer precursor, as shown with box 372. The carrier/diluent fluid may be similar to that flowed during depositing the first material layer 304 (shown in FIG. 4) and in this respect may include an inert gas such as nitrogen (N₂) gas or a noble gas such as argon (Ar), krypton (Kr), helium (He), and xenon (Xe), as also shown with box 372. The carrier/diluent fluid may include hydrogen (H₂) gas, as further shown with box 372. Advantageously, as shown in FIGS. 7 and 8, co-flowing nitrogen (N₂) gas with silicon-containing material precursors such as trisilane (Si₃H₈) and tetrasilane (Si₄H₁₀) may increase deposition rate of the second material, further increasing throughput of semiconductor processing systems employed for the material layer deposition method 300.

Exposing 360 the substrate to the first material layer precursor during deposition of the second material layer may include exposing the substrate to the etchant fluid employed during deposition of the first material layer, e.g., the etchant fluid 20 (shown in FIG. 1), as shown with box 374. The etchant fluid may include a halogen-containing material, such as chlorine (Cl₂) gas and/or hydrochloric acid (HCl), as also shown with box 374. The etchant fluid may be co-flowed with the first material layer precursor such that the upper surface of the substrate is exposed to the etchant fluid, the lower surface of the substrate is etched by the etchant fluid, or both the upper surface and the lower surface of the substrate are etched during deposition of the second material layer, as further shown with box 374.

Exposing 360 the substrate to the first material layer precursor during deposition of the second material layer precursor includes flowing the first material layer precursor into the chamber body at a second material layer precursor flow rate, as shown with box 376. The second material layer precursor flow rate may be similar to the first material layer precursor flow rate, e.g., between about 25 milligrams per minute and about 275 milligrams per minute, as also shown with box 376. Exposing 376 the substrate to the first material layer precursor may include flowing the carrier/diluent fluid, and/or the etchant, at a second carrier/diluent fluid flow rate, as also shown with box 376. The second carrier/diluent fluid flow rate may be similar to the first carrier/diluent fluid flow rate employed during deposition of the first material layer and may be between about 5 standard liters per minute and about 20 standard liters per minute, as further shown with box 376.

Forming 362 the second material layer may include depositing the second material layer at a second material layer deposition rate that greater than about 5 angstroms per second, for example, between about 5 angstroms per second and about 40 angstroms per second, as shown with box 378. In certain examples of the present disclosure the second material layer deposition rate may be between about 5 angstroms per second and about 15 angstroms per second, or between about 15 angstroms per second and about 30 angstroms per second, or even between about 30 angstroms per second and about 45 angstroms per second, as also shown with box 378.

Forming 362 the second material layer may include forming the second material layer with a second material layer thickness that is between about 5 nanometers and about 50 nanometers, as shown with box 380. For example, the second material layer thickness may be between about 5 nanometers and about 20 nanometers, or between about 20 nanometers and about 35 nanometers, or even between about 35 nanometers and about 50 nanometers, as also shown with box 380.

Forming 362 the second material layer may include forming the second material layer with a second within-material layer germanium concentration uniformity, as shown with box 382. The second within-material layer germanium concentration uniformity may be less than about 2%, for example between about 2% and about 0.5%, as also shown with box 382. In certain examples of the present disclosure the within-material layer germanium concentration uniformity may be between about 2% and about 1.5%, or between about 1.5% and about 1%, or even between about 1% and about 0.5%, as further shown with box 382.

Forming 362 the second material layer may be accomplished within a first layer deposition interval that is between about 5 seconds and about 40 seconds, as shown with box 384. For example, the second material layer may be deposited during a second material layer deposition interval that is between about 5 seconds and about 12 seconds, or between about 12 seconds and about 19 seconds, or between about 19 seconds and about 26 seconds, as also shown with box 384. The second material layer may be deposited during a second material layer deposition interval that is between about 26 seconds and about 33 seconds or even between about 33 seconds and about 40 seconds, as further shown with box 384.

Depositing 308 the two or more material layer pairs onto the substrate may include depositing between 20 and 400 material layer pairs onto the substrate, as shown with box 386. For example, depositing 308 the two or more material layer pairs may include depositing between 20 material layer pairs and 96 material layer pairs, or between 96 material layer pairs and 172 material layer pairs, or between 172 material layer pairs and 248 material layer pairs, or between 248 material pairs and 324 material layer pairs, or even between 324 material layer pairs and 400 material layer pairs onto the substrate, as also shown with box 386. Depositing 308 the two or more material layer pairs onto the substrate may include forming a material layer stack having a height that extends between about 0.5 microns and about 40 microns above the upper surface of the substrate, as shown with box 388. In this respect the material layer stack may be formed with a material layer stack height that is between about 0.5 microns and about 10 microns, or between about 10 microns and about 20 microns, or between about 20 microns and about 30 microns, or even between about 30 microns and about 40 microns, as further shown with box 388.

With reference to FIG. 7, depositing 308 (shown in FIG. 4) the two or more material layer pairs onto the substrate may include controlling 390 temperature with a plurality of temperature sensors. In this respect a first temperature measurement may be acquired with a first temperature sensor and a second temperature measurement acquired with a second temperature sensor, as shown with box 392 and box 394. A temperature differential may be determined between the first temperature measurement and the second temperature measurement, as shown with box 396. The temperature differential may be compared to a predetermined temperature differential, as shown with box 398, heat communicated into the chamber arrangement throttled when the temperature differential is greater than the predetermined temperature differential, as shown with box 301 and arrow 303. When the temperature differential is less than the predetermined temperature differential heating of the substrate may be maintained, and temperature monitoring continue, as shown with arrow 305.

When the temperature differential exceeds the predetermined temperature differential one or more of the plurality of heater elements supported above the chamber body housing the substrate may be throttled to adjust heat communicated into the interior of the chamber body, as shown with arrow 307 and box 309. For example, one or more heater elements overlaying the substrate may be throttled when the temperature differential is greater than the predetermined temperature differential, as shown with box 311. One or more heater elements overlaying the divider may be throttled when the temperature differential is greater than the predetermined temperature differential, as show with box 313. It is also contemplated that heater elements overlay both the substrate and the divider may be throttled when the temperature differential is greater than the predetermined temperature differential, as also shown with box 309. Additional temperature measurements may be thereafter acquired, for example, to determine the associated effect of throttling heat output on temperature differential as well as to continue monitoring of substrate temperature, as shown with arrow 315.

When the temperature differential exceeds the predetermined temperature differential one or more of the plurality of heater elements supported below the chamber body housing the substrate may also (or alternatively) be throttled to adjust heat communicated into the interior of the chamber body, as shown with box 317. For example, one or more heater elements underlying the substrate may be throttled when the temperature differential is greater than the predetermined temperature differential, as shown with box 319. One or more heater elements underlying the divider may be throttled when the temperature differential is greater than the predetermined temperature differential, as show with box 321. And heater elements underlying both the substrate and the divider may be throttled when the temperature differential is greater than the predetermined temperature differential, as also shown with box 317. Additional temperature measurements may also be thereafter acquired, as also shown with arrow 315.

In certain examples, the first temperature measurement and the second temperature measurement may be acquired using one or more of the first non-contact temperature sensor 132 (shown in FIG. 2) and the second non-contact temperature sensor 134 (shown in FIG. 2) to control average substrate temperature, as shown with box 323. In this respect it is contemplated that (a) at least one of the first temperature measurement and the second temperature measurement be acquired using the first non-contact temperature sensor 132 and the second non-contact temperature sensor 134, (b) the first temperature measurement and the second temperature measurement be averaged, and (c) heat communicated into the chamber arrangement be throttled according differential between the average temperature and the first predetermined material layer deposition temperature and/or the second predetermined material layer deposition temperature. As will be appreciated by those of skill in the art in view of the present disclosure, the first temperature measurement and the second temperature measurement may be acquired in substantially real-time with temperature change of the substrate and/or the material layer stack during deposition onto the substrate. As will also be appreciated by those of skill in the art in view of the present disclosure, real-time control of average temperature may in turn limit variation in layer-to-layer thickness variation within the material layer stack, improving reliability of semiconductor devices formed using the material layer stack.

In certain examples, alternatively (or additionally) the first temperature measurement and the second temperature measurement acquired by the first non-contact temperature sensor 132 and the second non-contact temperature sensor 134 may be employed to control center-edge temperature variation across the substrate, as shown with box 325. In this respect it is contemplated that (a) the first temperature measurement and the second temperature measurement be acquired using the first non-contact temperature sensor 132 and the second non-contact temperature sensor 134, (b) a center-to-edge temperature differential be determined using the first temperature measurement and the second temperature measurement, and (c) heat communicated into the chamber arrangement be varied (throttled) longitudinally along the surface of the substrate (e.g., in the general direction of flow of the material layer precursor 10 through the upper chamber of the chamber body) based on differential between the determined center-to-edge temperature differential and a predetermined center-to-edge temperature differential value. As will be appreciated by those of skill in the art in view of the present disclosure, controlling center-to-edge temperature variation using real-time temperature measurements acquired using the first non-contact temperature sensor 132 and the second non-contact temperature sensor 134 may limit within layer thickness variation and/or germanium concentration variation. As will also be appreciated by those of skill in the art in view of the present disclosure, limiting cross-substrate material layer thickness variation and/or germanium concentration may also limit variation in electrical properties of semiconductor devices formed using the material layer stack. To further advantage, the predetermined center-to-edge temperature differential may be employed to compensate for center-to-edge material layer thickness variation otherwise characteristic of the chamber arrangement, enablement of employment of the chamber arrangement in deposition operations otherwise made more difficult due to such characteristic center-to-edge material layer thickness variation.

In certain examples, the first temperature measurement and the second temperature measurement may be indicative of temperature of the substrate and the divider 138 (shown in FIG. 2), respectively, as shown with box 327. In this respect it is contemplated that (a) the first temperature measurement be acquired from the contact temperature sensor 136A (shown in FIG. 1); (b) the second temperature measurement be acquired using either of the first non-contact temperature sensor 132, the second non-contact temperature sensor 134, and/or the contact temperature sensor 136B; (c) the temperature differential between first temperature measurement and the second temperature measurement be compared to a predetermined divider-to-substrate temperature differential; and (d) that heat communicated into the chamber arrangement be varied longitudinally based on the comparison. Advantageously, controlling temperature within the chamber arrangement according to the predetermined divider-to-substrate differential enables controlling availability of silicon within flow of the material layer precursor 10 at the edge of substrate, for example, by throttling the extent of silicon-containing precursor decomposition upstream of the substrate according to divider temperature. As will be appreciated by those of skill in the art in view of the present disclosure, throttling available silicon at the edge of the substrate also enables control of cross-material layer thickness variation and/or germanium concentration, also limiting variation in electrical properties of semiconductor devices fabricated using the material layer stack 200 otherwise associated with such within-material thickness variation and/or germanium concentration variation.

With reference to FIG. 8, a graph 400 illustrating deposition rates as a function of temperature for silicon and silicon-germanium material layers using trisilane (Si₃H₈) are shown. As shown with traces 402 and 404, employment of trisilane (Si₃H₈) as the first material layer precursor 14 (shown in FIG. 2) enables deposition of silicon-germanium and silicon layers at deposition rates greater than other silicon-containing precursors, e.g., silane (SiH₄) and dichlorosilane (DCS), at material layer deposition temperatures provided by certain single-substrate chamber arrangements, e.g., the chamber arrangement 104 (shown in FIG. 1), improving throughput of such chamber arrangements. As shown with traces 406 and 408, employment of trisilane (Si₃H₈) enables deposition of silicon-germanium and silicon layers at even higher deposition rates greater than other silicon-containing precursors at material layer deposition temperatures provided by certain single-substrate chamber arrangements when co-flowed with nitrogen (N₂), e.g., as the carrier/diluent fluid 18 (shown in FIG. 2), further improving throughput of such chamber arrangements.

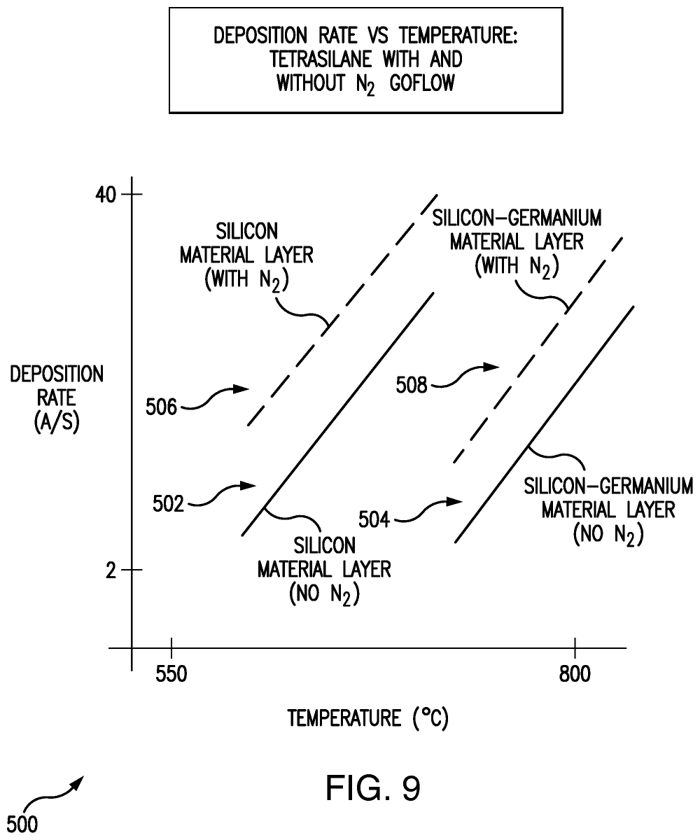

With reference to FIG. 9, a graph 500 illustrating deposition rates as a function of temperature for silicon and silicon-germanium material layers using tetrasilane (Si₄H₁₀) are shown. As shown with traces 502 and 504, employment of tetrasilane (Si₄H₁₀) as the first material layer precursor 14 (shown in FIG. 2) also enables deposition of silicon-germanium and silicon layers at deposition rates greater than other silicon-containing precursors, e.g., trisilane (S₃H₈), at material layer deposition temperatures provided by certain single-substrate chamber arrangements, e.g., the chamber arrangement 104 (shown in FIG. 1), also improving throughput of such chamber arrangements. As shown with traces 506 and 508, employment of tetrasilane (Si₄H₁₀) enables deposition of silicon-germanium and silicon layers at even higher deposition rates greater than other silicon-containing precursors at material layer deposition temperatures provided by certain single-substrate chamber arrangements when co-flowed with nitrogen (N₂), e.g., as the carrier/diluent fluid 18 (shown in FIG. 2), further improving throughput.

Semiconductor devices architectures are commonly scaled to increase performance, typically by increasing device density. Scaling generally proceeds until a limit is reached—at which point the architecture of the semiconductor device may be changed to realize further performance improvement and enable progressive improvement thereafter through further scaling of the architecture. Such architecture changes, though advantageous, typically entail significant costs due to need to develop the architecture and associated fabrication techniques for new architectures.

In examples described herein material layer deposition methods, semiconductor processing systems, and computer program products are provided that enable further scaling of device architectures using single-substrate chamber arrangements while limiting (or eliminating) the throughput disadvantage otherwise associated with single-substrate chamber arrangements. In certain examples a high order silicon-containing material layer precursor is employed in the material layer deposition methods, for example, trisilane and/or tetrasilane, to fabricate semiconductor devices. Advantageously, such precursors provide relatively high material layer deposition rates, offsetting or even exceeding the throughput advantages otherwise associated with mini-batch and batch-type process modules. In accordance with certain examples, the high order silicon-containing material layer precursors are co-flowed with nitrogen (N₂) gas, increasing deposition rate of the material layers forming the substrate owing to the tendency of nitrogen (N₂) gas to passivate the deposition surface, further reducing the throughput disadvantages otherwise associated with single-substrate semiconductor processing system in relation to mini-batch and batch-type semiconductor processing systems.

In certain examples, single-substrate semiconductor processing systems may employ temperature sensors and control methods that sharpen the advantage that single-substrate semiconductor processing systems typically enjoy over mini-batch and batch-type semiconductor processing system. For example, non-contact temperature sensors supported outside of the chamber arrangement employed to deposit the material layer stack onto the substrate may be employed to provide real-time temperature control and/or real-time cross-substrate temperature variation, limiting either (or both) layer-to-layer thickness variation as well as within-material layer thickness and/or germanium concentration variation. Contact sensors arranged within the chamber arrangement, either independent of the non-contact temperature sensor or in cooperation therewith, may also be employed to control substrate temperature as well as center-to-edge substrate temperature variation. Alternatively or additionally, one or more of the contact temperature may also be employed to control divider-to-substrate temperature differential, further limiting within-material layer variation by controlling the amount of available silicon at the edge of the substrate by throttling decomposition of the high order silicon-containing material layer precursor above the divider and upstream of the substrate relative to the general direction of material layer precursor flow through the chamber arrangement.

Although this disclosure has been provided in the context of certain examples and examples, it will be understood by those skilled in the art that the disclosure extends beyond the specifically described examples to other alternative examples and/or uses of the examples and obvious modifications and equivalents thereof. In addition, while several variations of the examples of the disclosure have been shown and described in detail, other modifications, which are within the scope of this disclosure, will be readily apparent to those of skill in the art based upon this disclosure. It is also contemplated that various combinations or sub-combinations of the specific features and aspects of the examples may be made and still fall within the scope of the disclosure. It should be understood that various features and aspects of the disclosed examples can be combined with, or substituted for, one another in order to form varying modes of the examples of the disclosure. Thus, it is intended that the scope of the disclosure should not be limited by the particular examples described above.

The headings provided herein, if any, are for convenience only and do not necessarily affect the scope or meaning of the devices and methods disclosed herein.

1. A material layer deposition method, comprising:
supporting one and only one substrate in a chamber arrangement;
exposing the substrate to a first material layer precursor and a second material layer precursor;
forming a first material layer overlaying the substrate using the first material layer precursor and the second material layer precursor;
exposing the first material layer to the first material layer precursor;
forming a second material layer onto the first material layer using the first material layer precursor;
wherein the second material layer precursor includes a germanium-containing material layer precursor; and
wherein the first material layer precursor includes at least one of trisilane (Si₃H₈) and tetrasilane (Si₄H₁₀).

2. The material layer deposition method of claim 1, wherein the first material layer precursor consists essentially of trisilane (Si₃H₈).

3. The material layer deposition method of claim 1, wherein the first material layer precursor consists essentially of tetrasilane (Si₄H₁₀).

4. The material layer deposition method of claim 1, further comprising co-flowing the first material layer precursor with a carrier/diluent fluid including nitrogen (N₂) gas.

5. The material layer deposition method of claim 1, further comprising:
maintaining a first material layer deposition pressure within the chamber arrangement that is between about 1 Torr and about 50 Torr during forming the first material layer onto the substrate; and
maintaining a second material layer deposition pressure within the chamber arrangement that is between about 1 Torr and about 50 Torr during forming the second material layer onto the first material layer.

6. The material layer deposition method of claim 1, further comprising:
maintaining the substrate at a first material layer deposition temperature that is between about 500 degrees Celsius and about 800 degrees Celsius during forming the first material layer overlaying the substrate; and
maintaining the substrate and the first material layer at a second material layer deposition temperature that is between about 500 degrees Celsius and about 800 degrees Celsius during forming the second material layer onto the first material layer.

7. The material layer deposition method of claim 1, wherein forming the first material layer onto the substrate comprises forming the first material layer at a first material layer deposition rate that is between about 12 angstroms per second and about 60 angstroms per second.

8. The material layer deposition method of claim 1, wherein forming the second material layer onto the substrate comprises forming the second material layer at a second material layer deposition rate that is between about 5 angstroms per second and about 40 angstroms per second.

9. The material layer deposition method of claim 1, further comprising:
acquiring a first temperature measurement and a second temperature measurement;
determining a differential between the first temperature measurement and the second temperature measurement;
comparing the differential to a predetermined temperature differential; and
throttling heat communicated into the chamber arrangement when the differential is greater than the predetermined temperature differential.

10. The material layer deposition method of claim 9, wherein throttling heat communicated into the chamber arrangement further comprises:
throttling one or more of a plurality of upper heater elements supported above the chamber arrangement relative to another of the upper heater elements; and
throttling one or more of a plurality of lower heater elements supported below the chamber arrangement relative to another of the lower heater elements.

11. The material layer deposition method of claim 9, wherein the differential is an average substrate temperature differential, the method further comprising controlling average substrate temperature using the first temperature measurement and the second temperature measurement.

12. The material layer deposition method of claim 9, wherein the differential is a center-to-edge substrate temperature differential, the method further comprising controlling a center-to-edge temperature differential of the substrate using the first temperature measurement and the second temperature measurement.

13. The material layer deposition method of claim 9, wherein the differential is a divider-to-substrate temperature differential, the method further comprising controlling a divider-to-substrate temperature differential using the first temperature measurement and the second temperature measurement.

14. The material layer deposition method of claim 9, wherein (a) the first temperature measurement and the second temperature measurement are acquired optically, (b) the first temperature measurement is acquired optically and the second temperature measurement is acquired tactilely, and (c) the first temperature measurement and the second temperature measurement are acquired tactilely.

15. The material layer deposition method of claim 1, further comprising forming a 3D DRAM semiconductor device using the first material layer and the second material layer.

16. A material layer stack comprising between 20 material layer pairs and 400 material layer pairs overlaying a substrate, wherein each of the between 20 material layer pairs and 400 material layer pairs includes a first material layer and a second material layer deposited using the material layer deposition method of claim 1.

17. The material layer stack of claim 15, wherein the first material layer and the second material layer have thicknesses that are between about 5 nanometers and about 50 nanometers, wherein the first material layers have a within-material layer thickness variation that is between about 1 nanometer and about 0.2 nanometers, and wherein the second material layers have a within-material layer thickness variation that is between about 2 nanometers and about 0.4 nanometers.

18. The material layer stack of claim 15, wherein the first material layers of the between 20 material layer pairs and 400 material layer pairs have layer-to-layer thickness variation that is less than about 2 nanometers, and the second material layers of the between 20 material layer pairs and the 400 material layer pairs have layer-to-layer thickness variation that is less than about 10 nanometers.

19. A semiconductor processing system, comprising:
a precursor arrangement configured to provide a first material layer precursor and a second material layer precursor, wherein the second material layer precursor includes a germanium-containing material layer precursor, and wherein the first material layer precursor includes at least one of trisilane (Si₃H₈) and tetrasilane (Si₄H₁₀);
a chamber arrangement connected to the precursor arrangement and housing a substrate support, the substrate supported support for rotation about a rotation axis; and
a controller operably connected to the chamber arrangement and the precursor delivery arrangement, the controller include a processor disposed in communication with a memory, the memory including a non-transitory machine-readable medium having a plurality of program modules containing instructions that, when read by the processor, cause the processor to:
support one and only one substrate within the chamber arrangement;
expose the substrate to a first material layer precursor and a second material layer precursor;
form a first material layer overlaying the substrate using the first material layer precursor and the second material layer precursor;
expose the first material layer to the first material layer precursor; and
form a second material layer onto the first material layer using the first material layer precursor.

20. A computer program product, comprising:
a non-transitory machine-readable medium having a plurality of program modules recorded thereon containing instructions that, when read by a processor, cause the processor to execute operations to:
support one and only one substrate in a chamber arrangement of a semiconductor processing system;
expose the substrate to a first material layer precursor and a second material layer precursor provided by a precursor delivery arrangement connected to the chamber arrangement;
form a first material layer overlaying the substrate using the first material layer precursor and the second material layer precursor;
expose the first material layer to the first material layer precursor;
form a second material layer onto the first material layer using the first material layer precursor;
wherein the second material layer precursor includes a germanium-containing material layer precursor; and
wherein the first material layer precursor includes at least one of trisilane (Si₃H₈) and tetrasilane (Si₄H₁₀).
